(19) United States
(12) Patent Application Publication
(10) Pub. No.: US 2025/0323058 A1
(43) Pub. Date: Oct. 16, 2025

(54) METHOD FOR ETCHING RUTHENIUM

(71) Applicant: Applied Materials, Inc., Santa Clara, CA (US)

(72) Inventors: Zhiren LUO, Santa Clara, CA (US); Lei LIAO, San Jose, CA (US); Jeong Hwan KIM, San Jose, CA (US); Qian FU, San Jose, CA (US)

(21) Appl. No.: 18/631,989

(22) Filed: Apr. 10, 2024

(51) Int. Cl. H01L 21/3213; H01L 21/67

(52) U.S. Cl. CPC H01L 21/32136; H01L 21/32139; H01L 21/67069

(57) ABSTRACT

Disclosed herein are methods for etching ruthenium (Ru) at low temperatures, and a processing chamber for performing the same. In one example, a method for etching ruthenium (Ru), includes exposing a portion of a substrate containing an exposed Ru layer to a processing gas comprising a halogen containing gas and an oxygen containing gas, wherein the substrate is disposed on a substrate support in a processing chamber; and maintaining a temperature of the substrate support between −90° C. and 20° C. while exposing the portion of the Ru layer to the halogen containing gas.

### BACKGROUND

### Field

Embodiments of the present disclosure generally relate to ruthenium etching, in particular, embodiments herein relate to a method of ruthenium subtractive etching of logic backend lines at a cryogenic temperature.

### Description of the Related Art

Back-end-of-line (BEOL) interconnects are an important part of the semiconductor manufacturing process. BEOL interconnects are formed to interconnect individuals devices (i.e., transistors and capacitors) via wiring on a wafer. Ruthenium (Ru) is currently being explored as potential replacement for copper (Cu) in back-end-of-line (BEOL) interconnects, particularly for the tightest pitch features in future technology nodes. Currently, the subtractive etching of Ru is performed at room temperature ranges with a small pitch. However, the current methods of etching Ru yield interconnects with inconsistent roughness, leading to high electrical resistance and low device quality. Thus, current subtractive Ru etching techniques may be challenging for reliable use at smaller technology nodes.

Therefore, there is a need in the art for an improved method of etching Ru with improved roughness.

### SUMMARY

Described herein are techniques for etching ruthenium (Ru) at low temperatures, and a processing chamber for etching the same. In one example, a method for etching ruthenium (Ru), includes exposing a portion of a substrate containing an exposed Ru layer to a processing gas comprising a halogen containing gas and an oxygen containing gas, wherein the substrate is disposed on a substrate support in a processing chamber; and maintaining a temperature of the substrate support between-90° C. and 20° C. while exposing the portion of the Ru layer to the halogen containing gas.

In another example, a method of etching ruthenium (Ru) includes exposing a portion of a substrate containing an exposed Ru layer to a processing gas comprising a halogen containing gas and an oxygen containing gas, the halogen containing gas is Cl₂, the oxygen containing gas is O₂, wherein a ratio of Cl₂ to O₂ is between 1:20 to 1:1 standard cubic centimeters per minute (sccm), wherein the substrate is disposed on a substrate support in a processing chamber; and maintaining a temperature of the substrate support between-70° C. to −20° C. while exposing the portion of the Ru layer to the halogen containing gas.

In yet another example, a processing chamber is provided that includes a chamber body having a processing volume, a substrate support disposed in the processing volume, a controller, and a memory storing instruction. The instructions, when executed by the controller, causes a method for forming a feature on a substrate disposed on the substrate support to be performed, the method comprising exposing a portion of a substrate containing an exposed Ru layer to a processing gas comprising a halogen containing gas and an oxygen containing gas, wherein the substrate is disposed on a substrate support in a processing chamber; maintaining a temperature of the substrate support between −90° C. and 20° C. while exposing the portion of the Ru layer to the halogen containing gas.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional side view of a process chamber, according to embodiments of the present disclosure.

FIG. 2 is a schematic block diagram illustrating a controller of a process chamber, according to embodiments of the present disclosure.

FIGS. 3A-3B illustrate cross-sectional views of a film stack having an Ru layer at different stages of a subtractive etching process of the Ru layer, according to embodiments of the present disclosure.

FIGS. 4A-4B illustrate cross-sectional views of a film stack having an Ru layer at different stages of a Ru layer where pressure is lower but temperature is constant, according to embodiments of the present disclosure.

FIG. 5 is a flow diagram of a method for subtractive etching of a Ru layer.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

When forming BEOL interconnects in a Ru layer, roughness of the BEOL interconnects may be reduced by etching at low temperature (i.e., cryogenic temperatures). When temperature is low, oxidation by-products formed from the exposure of the Ru layer to processing gases become less volatile and serve as passivation to cover the side walls of the interconnect, leading to reduced roughness. In addition, the lower atom energy at low temperatures leads to less chemisorption and more physisorption, resulting in a smaller etching rate and better sidewall passivation. Thus, by etching Ru layers at low temperatures, roughness is improved (i.e., reduced) without requiring increased amounts of passivation gases, which streamlines the etching process and reduces costs, while improving the tuning ability and flexibility of etch processes. Furthermore, the novel low temperature process has improved selectivity, resulting in reduced hard mask, overhang metal, and underlayer metal consumption during the etching process, which leads to a better quality device.

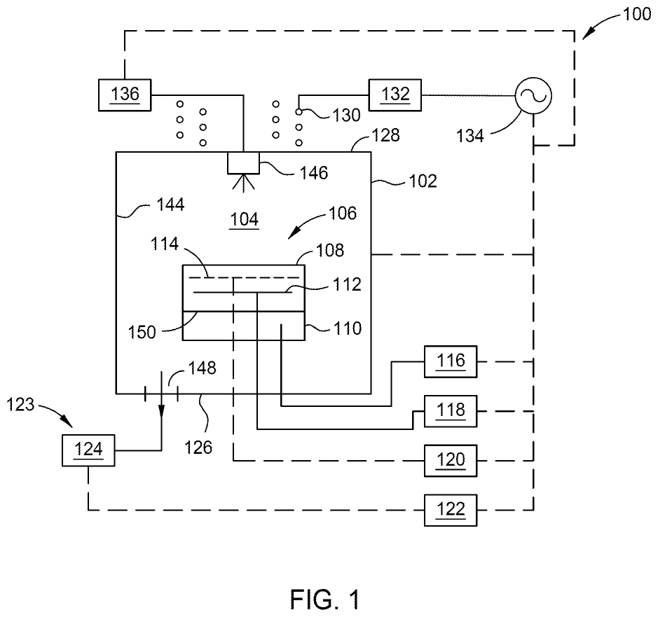

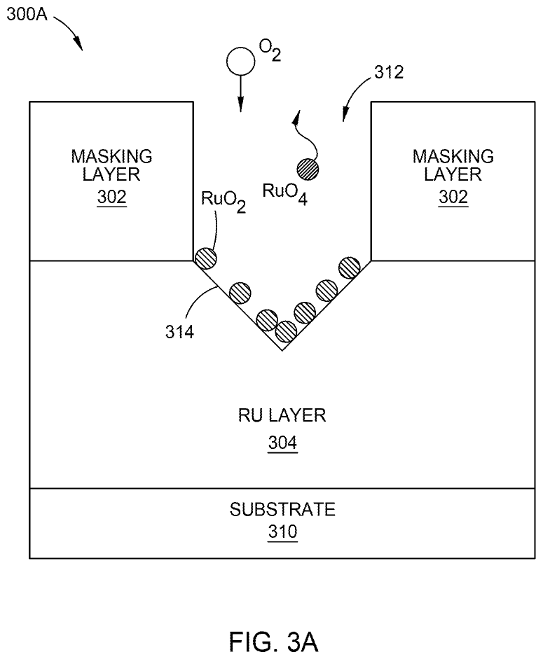

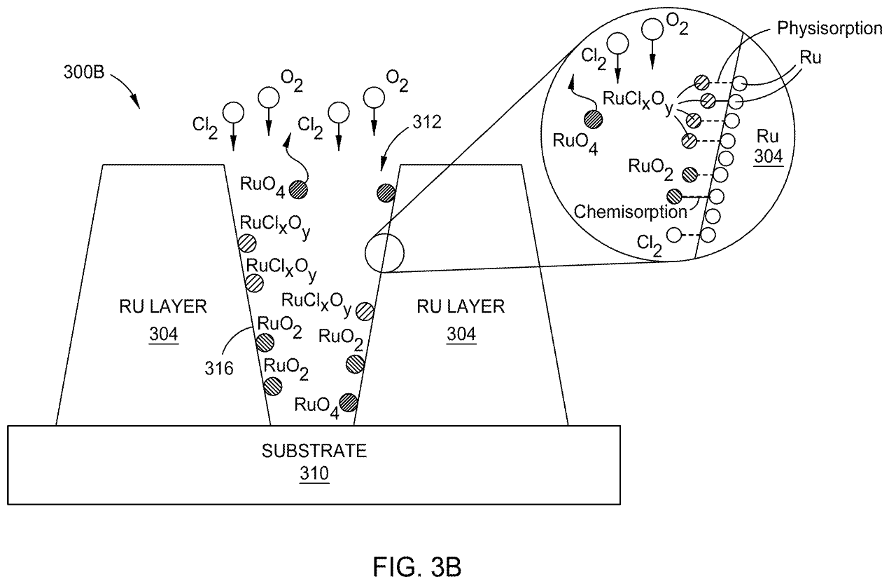

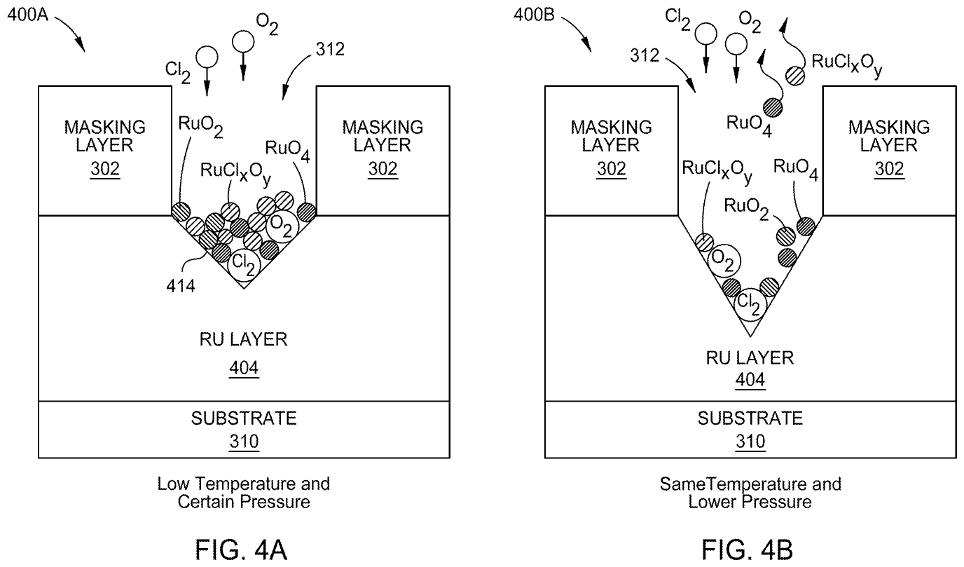

FIG. 1 is a cross-sectional schematic view of an exemplary plasma processing chamber 100, shown configured as an etch chamber, having a substrate support assembly 106. The processing chamber 100 is an example chamber that may be used to perform the method discussed in FIGS. 3A-3B and FIGS. 4A-4B, among other processes. The substrate support assembly 106 is configured to maintain a surface or workpiece, such as a substrate, at a cryogenic processing temperatures.

The processing chamber 100 includes a chamber body 102 having chamber sidewalls 144, a chamber bottom 126 and a removably coupled lid 128 that enclose an inner volume 104. The chamber lid 128 is coupled to a gas panel 136 to allow gases to be provided into the inner volume 104 through an injection apparatus 146. In some examples, the gas panel 136 provides purging, cleaning, process, and/or additive gases to the inner volume 104. In one example, the gas panel 136 includes Cl₂, O₂, CF₄, CHF₃, N₂, CH₄, HBr, CH₂F₂, CH₃F, SOCl₂, COS, SO₂, and SF₆. The chamber lid 128 also supports an RF coil 130. The RF coil 130 is energizable by a RF power supply 134. The RF power supply 134 provides RF power through a RF matching circuit 132 to the RF coil 130. In some examples, the RF matching circuit 132 conditions the RF power to a suitable impedance to improve performance in the RF coil 130. In some examples, the energized RF coil 130 excites the process gases to create a plasma within the inner volume 104. Process gases, along with any processing by-products, are removed from the inner volume 104 through an exhaust port 148 formed in the chamber sidewalls 144 or chamber bottom 126 of the chamber body 102. The exhaust port 148 is coupled to a pumping system 123, which includes throttle valves and pumps (not shown) utilized to control the vacuum levels within the inner volume 104.

The substrate support assembly 106 is disposed within the inner volume 104. The substrate support assembly 106 is configured to receive, support, and process a substrate thereon. In some examples, the substrate support assembly 106 comprises an electrostatic chuck 108 having bottom 150 disposed on a cooling base 110. The electrostatic chuck 108 is configured to generate electrostatic to secure a substrate (not shown) thereon during processing. The electrostatic chuck 108 includes a chucking electrode 114 that is connected to a chucking electrode power supply 120. When energized, the chucking electrode 114 generates the electrostatic force that secures the substrate to the electrostatic chuck. The cooling base 110 is configured to remove thermal energy from the substrate support assembly 106. The processing chamber 100 is a cryogenic enabled chamber wherein the cooling base 110 is configured to reduce the temperature of the substrate support assembly 106 to less than 0 degrees Celsius. The temperature of the cooling base 110 is regulated by flowing a temperature regulating fluid there through. The cooling base 110 is coupled to a heat exchanger 116 to control the temperature of the temperature regulating fluid. In one example, the cooling base 110 may maintain the substrate support surface of the electrostatic chuck 108 at a temperature below 20° C., i.e. such as below 0° C., such as below −20° C., such as below-40° C., such as below −50° C., such as below −60° C., such as below −80° C., such as −90° C. The cooling base 110 may further maintain the substrate support surface of the electrostatic chuck 108 at a temperature in the range of between −90° C. and 20° C., such as between −70° C. and −20° C., such as between −70° C. and −40° C., such as −60° C. to −55° C.

In some examples, the substrate support assembly 106 may include a heater 112. The heater 112 may be disposed in the electrostatic chuck 108 or other component of the substrate support assembly 106. The heater 112 is used to control the temperature of the substrate support assembly. In one example, the heater 112 is a resistive heating element coupled to a heater power supply 118. Power provided by the heater power supply 118 to the heater 112 is used to help regulate the temperature of the substrate support assembly 106 in concert with the cooling base 110.

A controller 122 is coupled to the processing chamber 100. The controller 122 is utilized to control the functionality of the processing chamber 100, including substrate processing and chamber cleaning operations. For example, the controller 122 is configured to enable the method discussed in FIGS. 3A-3B and FIGS. 4A-4B, among other processes, to be performed in the processing chamber 100. The controller 122 is also configured to receive data or input from sensor readings from a plurality of sensors and send or output instructions to various process chamber components or equipment. The controller 122 is equipped with or in communication with a system model (not shown) of the processing chamber 100. The system model is a program configured to estimate parameters (such as a gas flow rate, a gas pressure, a processing temperature, a rotational position of component(s), a heating profile, and/or a cleaning condition) within the processing chamber 100 throughout a processing operations and/or a cleaning operation. The controller 122 is further configured to store readings and calculations. The readings and calculations include previous sensor readings, such as any previous sensor readings within the processing chamber 100. The readings and calculations further include the stored calculated values from after the sensor readings are measured by the controller 122 and run through the system model. Therefore, the controller 122 is configured to both retrieve stored readings and calculations as well as save readings and calculations for future use. Maintaining previous readings and calculations enables the controller 122 to adjust the system model over time to reflect a more accurate version of the processing chamber 100.

The controller 122 can monitor, estimate an optimized parameter, adjust an initiated operation, generate an alert on a display, halt an operation, initiate a chamber downtime period, delay a subsequent iteration of an operation, initiate a cleaning operation, halt a cleaning operation, adjust a heating power, and/or otherwise adjust the process recipe. In one or more examples, the controller 122 is communicatively coupled to and controls the operation of at least the heat exchanger 116, the heater power supply 118, the chucking electrode power supply 120, the RF power supply 134, the gas panel 136, the vacuum pump 124, and auxiliary chamber components (not shown) within the chamber body 102.

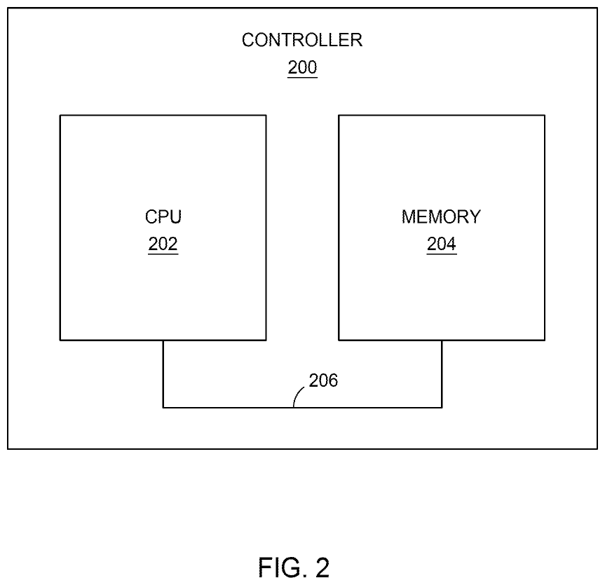

FIG. 2 is a schematic block diagram of the controller 122 of the process chamber 100 illustrated in FIG. 1. The controller 122 includes a central processing unit (CPU) 202 (e.g. a processor), a memory 204 containing instructions, and support circuits 206 for the CPU 202. The controller 122 controls various items directly, or via other computers and/or controllers.

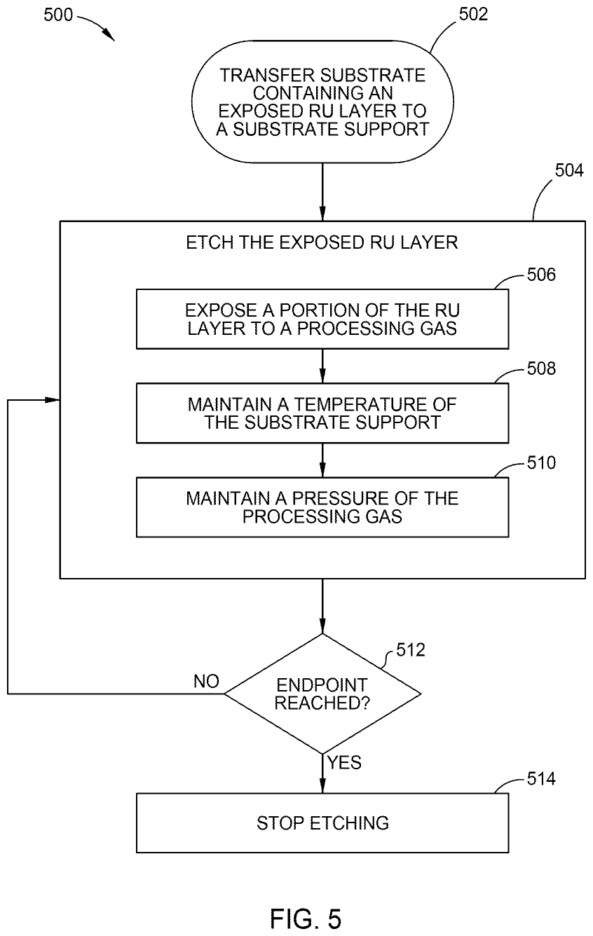

FIGS. 3A-3B and 4A-4B illustrate cross-sectional views of a film stack having an Ru layer at different stages of a subtractive etching process 500 illustrated in the flow diagram of FIG. 5. The following description refers simultaneously to both the subtractive etching process 500 and the cross-sectional views of FIGS. 3A-3B and 4A-4B. The subtractive etching process 500 may be stored as instructions in the memory 204, which when executed by the CPU 202 of the controller 122, causes the method 500 to etch the RU layer exposed in the film stacks 300A, 300B, 400A and 400B illustrated in FIGS. 3A-3B and 4A-4B.

The subtractive etching process 500 of a Ru layer 304 starts at operation 502 by transferring a substrate 310 having a film stack 300A containing the Ru layer 304 disposed thereon onto a substrate support assembly 106 disposed in a processing chamber 100, as depicted in FIG. 3A. In one example, the film stack 300A includes a masking layer 302 formed over the Ru layer 304. The Ru layer 304 is formed on substrate 310. Although the Ru layer 304 is described as being disposed on the substrate 310, additional intervening layers may be formed between the substrate 310 and the exposed Ru layer 304.

In one example, the masking layer 302 may be a hardmask layer. The hardmask layer may be fabricated from titanium nitride (TIN), tantalum nitride (TaN), silicon nitride (SIN), silicon or the like. Alternatively, the masking layer 302 may be a patterned resist layer or a carbon containing layer. The masking layer 302 is patterned with at least one opening 312 that expose portions 314 of the Ru layer 304. The pattern of the masking layer 302 corresponds to desired feature(s) to be etched into the Ru layer 304 through the openings 312. Although only a single opening 312 is shown through the masking layer 302 in FIG. 3A and FIGS. 4A-4B, it is understood that many additional openings 312 may be formed through the masking layer 302 to expose portions 314 of the Ru layer 304.

At operation 504, the Ru layer 304 is etched, as depicted in FIGS. 3A-3B. At operation 504, the exposed portion 314 of the Ru layer 304 is incrementally etched through the opening 312 of the masking layer 302. In one or more examples, etching the Ru layer 304 at operation 504 includes operations 506-510.

At operation 506, the exposed portion 314 of the Ru layer 304 is exposed to processing gases comprising a halogen containing gas and an oxygen containing gas, as illustrated in FIG. 3A-3B and FIG. 4A-4B. In one or more examples, the halogen containing gas is a chlorine containing gas, such as Cl₂, or the like. In one or more examples, the oxygen containing gas is O₂, or the like. The halogen and oxygen containing gases are provided by the gas panel into the internal volume of the processing chamber.

In one or more examples, the oxygen containing gas is flowed into the processing chamber at a flow rate between 50 standard cubic centimeters per minute (sccm) to 1000 sccm, such as 200 sccm to 600 sccm, or 300 sccm to 600 sccm. The oxygen containing gas is flowed into the processing chamber via a gas panel and an injection apparatus (e.g. gas panel 136 and injection apparatus 146 of FIG. 1). The oxygen containing gas makes contact with the exposed portions 314 of the Ru layer 304 through the opening 312 of the masking layer 302. Due to the chemistries of the Ru layer 304 and the oxygen containing gas, the oxygen containing gas is physically absorbed (i.e. undergoes physisorption) by the exposed portion 314 of the Ru layer 304 and oxidation by-products non-volatile RuO₂ and volatile RuO₄ are produced. However, chemisorption dominates at room temperature with high atom energy, leading to a large etching rate, vertical profile, limited passivation, and rough sidewalls of the interconnect. The prevalent chemisorption leads to non-volatile RuO₂ that is deposited on the exposed portion 314 of the Ru layer 304 being not easily removed, therefore blocking subsequent action processes between the oxygen containing gas and the exposed portion 314 of the Ru layer 304, which in turn, decreases etching rate. For example, as depicted in the film stack 300A of FIG. 3A, the oxygen containing gas contacts the exposed portion 314 of the Ru layer 304 through opening 312 formed in the masking layer 302 to a produce oxidation by-products (i.e. non-volatile RuO₂ and volatile RuO₄). Volatile RuO₄ is easily removed; however, non-volatile RuO₂ blocks the exposed portion 314 of the Ru layer 304 hindering any subsequent action processes between the oxygen containing gas and the Ru layer 304. The addition of a halogen containing gas (e.g. a chlorine containing gas) increases the etching rate by the effect of ClO neutrals and ClO₊/ClO₂₊ ions, which helps convert non-volatile RuO₂ to volatile RuO₃ (not shown), RuO₄, and RuOₓCl_{y}.

In one or more examples, the halogen containing gas is flowed into the processing chamber at a flow rate between 30 sccm to 300 sccm, such as 60 sccm to 200 sccm, as illustrated in FIG. 3B. In one or more examples, the halogen containing gas is flowed into the processing chamber via a gas panel and an injection apparatus (e.g. gas panel 136 and injection apparatus 146 of FIG. 1). The halogen containing gas makes contact with the oxidation by-products non-volatile RuO₂ and volatile RuO₄ through the opening 312 of the masking layer 302. Due to the chemistries of the halogen containing gas and the oxidation by-products, the effect of ClO neutrals and ClO₊/ClO₂₊ ions help convert the deposited non-volatile RuO₂ into volatile RuO₃ (not shown), RuO₄, and RuOₓCl_{y}. For example, as depicted in the film stack 300B of FIG. 3B, a halogen containing gas contacts the oxidation by-products, non-volatile RuO₂ and volatile RuO₄, through the opening 312 formed in the masking layer (not shown) to help convert the non-volatile RuO₂ to volatile RuO₃ (not shown), RuO₄, and RuOₓCl_{y}. In one or more examples, a lower ratio of Cl/(Cl₊O) means less RuO₂ is consumed, leading to smoother and more taper sidewalls of the interconnect. In one or more examples, the ratio of processing gases O₂ to Cl₂ is between 1:20 to 1, such as 1:10 to 1:3.

In one or more examples, optional additive gases are flowed into the processing chamber (not shown) at a flow rate of less than 120 sccm, such as less than 30 sccm, such as between 2.5 sccm to 10 sccm. The additive gases help form passivation of CFₓ, RuFₓ, RuS₂, RuSₓ, and/or SiOₓBr_{y}, which improve the sidewall profile. In one or more examples, the additive gases are one or more gases selected from a group consisting of CF₄, CHF₃, CH₂F₂, CH₃F, N₂, CH₄, HBr, SOCl₂, COS, SO₂, and SF₆. In one or more examples, additive gases (e.g. HBr) are flowed into the processing chamber at a flow rate of less than 100 sccm. In one or more examples, additive gases help form relative passivation of N₂. In one or more examples, additive gases (e.g. CH₄) help form passivation and carbon based disposition to protect the sidewall. In one or more examples, the ratio of additive gases to total gases in the processing chamber is about 0.01. In one or more examples, the subtractive etching process of the Ru layer 304 may be used to form an interconnect, where the Ru layer 304 has a thickness of up to 60 nm and a pitch size of 21 nm or greater.

In one or more examples, the deposited non-volatile RuO₂ are removed using a plasma formed from an inert gas (not shown). The deposited non-volatile RuO₂ are exposed to the plasma formed from an inert gas, such as He or Ar, through the masking layer 302. Inert gas ions formed in the plasma are directed into contact with the non-volatile RuO₂. The contact from the inert gas ions cause desorption of the non-volatile RuO₂. In one or more examples, the flow rate of the inert gas into the processing chamber is between 50 sccm and 1000 sccm, such as between 200 sccm to 600 sccm. In one or more examples, the ratio of inert gases to total gases in the processing chamber is about 1:3.

At operation 508, a temperature of the substrate support is maintained. In one or more examples, during the etching process at operation 506, the substrate supporting surface of the substrate support assembly is maintained at a cryogenic temperature below 20° C., i.e. such as below 0° C., such as below −20° C., such as below −40° C., such as below −50° C., such as below −60° C., such as below −80° C., such as −90° C. For example, maintaining the temperature of the substrate support between −90° C. and 20° C., such as between −70° C. and −20° C., such as between −70° C. and −40° C., such as −60° C. to −55° C. Performing the etching process at cryogenic temperatures result in an improved etching rate because when exposure (i.e. operation 506) occurs at room temperature chemisorption dominates with high atom energy, which leads to a lower etching rate, vertical profile, limited passivation, and the interconnect having rough sidewalls. Whereas when temperature is lower, particularly in cryogenic temperatures, volatile RuO₄ and RuOₓCl_{y} become less volatile and serves as passivation to cover the sidewalls of the interconnect 316 and improve roughness. That is, as temperature decreases, physisorption becomes more stable, which leads to more passivation and condensation on the surface of the sidewalls of the interconnect 316 and results in smoother sidewalls of the interconnect 316. Further, at low wafer temperature, lower atom energy leads to less chemisorption and more physisorption, which results in an improved etching rate and more passivation. In turn, more passivation further results in reduced roughness with a more tapered profile. For example, as further depicted in the film stack 300B of FIG. 3B, at cryogenic temperatures lower atom energy leads to less chemisorption and more physisorption, RuO₄ and RuOₓCl_{y} become less volatile and serve as passivation to cover the sidewalls of the interconnect 316 and improve roughness.

At operation 510, a pressure of the processing gases present within the processing chamber is maintained. In one or more examples, during the etching process at operation 506, the pressure within the internal volume of the chamber body is maintained between 2 mTorr to 60 mTorr, such as 10 mTorr to 20 mTorr. Below certain temperatures (e.g. at −90° C.), oxidation by-products RuO₃, RuO₄ and RuOₓCl_{y} are non-volatile and are deposited on the exposed portions 414 of the Ru layer 404. Thus, when exposed to the processing gases, the exposed portions 414 of the Ru layer 404 are blocked by the deposited oxidation by-products RuO₃ (not shown), RuO₄ and RuOₓCl_{y}, as illustrated in FIG. 4A. In one or more examples, this blockage may be due to more multiplayer-molecule physisorption and thicker condensation. However, based on isothermal reversibility (i.e. Langmuir and BET theory), etching at lower pressure can reverse the physisorption process, reduce condensation amount, and enable etching.

In one or more examples, based on saturated vapor pressure, the RuO₃ (not shown), RuO₄, and RuOₓCl_{y} are non-volatile at −90° C. and 10 mTorr (e.g. film stack 400A of FIG. 4A), but when under a lower pressure (e.g. −90° C. and 5 mTorr) RuO₃ (not shown), RuO₄, and RuOₓCl_{y} reverted back to a volatile state and etching is enabled despite the low temperature (e.g. film stack 400B of FIG. 4B). Thus, by pressure tuning the etching process at a constant temperature but at a lower pressure the working range (e.g. −90° ° C. to −40° C.) may be enlarged. For example, as depicted in the film stack of 400B in FIGS. 4A-B, RuO₃ (not shown), RuO₄, and RuOₓCl_{y} are reverted to a volatile state by etching at lower pressure. The lower pressure reverses the multiplayer-molecule physisorption process and etching is enabled,

In addition to maintaining a temperature of a substrate support and a pressure of the processing gases present within the processing chamber, increasing the over etch time of the subtractive etching process of a Ru layer 304 may also result in an improved profile footing of the interconnect without consuming the masking layer. In one or more examples, the over etch time may be increased from an over etch time of 30 to 60, or to 100.

At operation 512, whether the subtractive etching process of a Ru layer 304 has reached an endpoint is determined. In one example, the endpoint of the etching process 500 is reached when the top surface of the substrate 310 is exposed through the etched away portion of the Ru layer 304, 404 (i.e. the interconnect is etched through the entire Ru layer 304). Whether the endpoint of the etching process 500 is reached may be determined by checking the processing by-products exiting an exhaust port, such as exhaust port 148 of the etching chamber 102 (FIG. 1). If the material that comprises the substrate 310 is included in the by-products, then the top surface of the substrate (i.e., the endpoint) has been reached. On the other hand, if the material that comprises the substrate is not included in the by-products, then the top surface of the substrate (i.e., the endpoint) has not been reached. The end point may alternatively be determined via other techniques.

If the endpoint has not been reached, the etching process 500 continues at operation 504 to etch the Ru layer 303, 404 through the masking layer 302. If the endpoint has been reached, etching of the Ru layer 304, 404 is stopped at operation 514.

In an embodiment, the method of etching ruthenium (Ru) includes exposing a portion of a substrate containing an exposed Ru layer to a processing gas comprising a halogen containing gas and an oxygen containing gas, wherein the substrate is disposed on a substrate support in a processing chamber; maintaining a temperature of the substrate support between −90° C. and 20° C. while exposing the portion of the Ru layer to the halogen containing gas. The oxygen containing gas is O₂. The halogen gas contains a chlorine containing gas. The chlorine containing gas is Cl₂. The flow rate of Cl₂ is between 5 and 600 standard cubic centimeters per minute (sccm). The flow rate of Cl₂ is between 60 and 200 standard cubic centimeters per minute (sccm). Maintaining the temperature further comprises maintaining the temperature of the substrate support between −70° C. to −20° C. Maintaining the temperature further comprises maintaining the temperature of the substrate support between −60° C. to −55° C. Maintaining the processing gas present within the processing chamber at a pressure of between 2 and 60 mTorr. Maintaining the processing gas present within the processing chamber comprises further maintaining the processing gas between 10 and 20 mTorr. The processing gas includes at least one additive gas, the additive gas containing a halogen-based gas or a sulfuric-based gas. The processing gas includes at least one additive gas selected from the group consisting of CF₄, CHF₃, CH₂F₂, CH₃F, N₂, CH₄, HBr, SOCl₂, COS, SO₂, and SF₆. A ratio of the at least one additive gas to total gases is 0.01. Exposing the portion of the Ru layer to the processing gas further comprises forming a portion of an interconnect structure in the Ru layer.

In another embodiment, the method of etching ruthenium (Ru) includes exposing a portion of a substrate containing an exposed Ru layer to a processing gas comprising a halogen containing gas and an oxygen containing gas, the halogen containing gas is Cl₂, the oxygen containing gas is O₂, wherein a ratio of Cl₂ to O₂ is between 1:20 to 1:1 standard cubic centimeters per minute (sccm), wherein the substrate is disposed on a substrate support in a processing chamber; and maintaining a temperature of the substrate support between −70° C. to −20° C. while exposing the portion of the Ru layer to the halogen containing gas. The ratio of Cl₂ to O₂ further is 1:10 to 1:3 sccm. Forming an interconnect in the Ru layer, wherein an oxidation by-product of the exposing a portion of the Ru layer serves as passivation to cover at least one sidewall of the interconnect. The interconnect is tapered.

In yet another embodiment, a processing chamber configured to etch ruthenium (Ru) is provided. The processing chamber is provided that includes a chamber body having a processing volume, a substrate support disposed in the processing volume, a controller, and a memory storing instruction. The instructions, which, when executed by the controller, causes a method for forming a feature on a substrate disposed on the substrate support to be performed, the method comprising exposing a portion of a substrate containing an exposed Ru layer to a processing gas comprising a halogen containing gas and an oxygen containing gas, wherein the substrate is disposed on a substrate support in a processing chamber; maintaining a temperature of the substrate support between −90° C. and 20° C. while exposing the portion of the Ru layer to the halogen containing gas.

What is claimed is:

1. A method of etching ruthenium (Ru), the method comprising:
exposing a portion of a substrate containing an exposed Ru layer to a processing gas comprising a halogen containing gas and an oxygen containing gas, wherein the substrate is disposed on a substrate support in a processing chamber; and
maintaining a temperature of the substrate support between −90° C. and 20° C. while exposing the portion of the Ru layer to the halogen containing gas.

2. The method of claim 1, wherein the oxygen containing gas is O₂.

3. The method of claim 1, wherein the halogen gas contains a chlorine containing gas.

4. The method of claim 3, wherein the chlorine containing gas is Cl₂.

5. The method of claim 4, wherein a flow rate of Cl₂ is between 5 and 600 standard cubic centimeters per minute (sccm).

6. The method of claim 4, wherein a flow rate of Cl₂ is between 60 and 200 standard cubic centimeters per minute (sccm).

7. The method of claim 1, wherein maintaining the temperature further comprises maintaining the temperature of the substrate support between −70° C. to −20° C.

8. The method of claim 1, wherein maintaining the temperature further comprises maintaining the temperature of the substrate support between −60° C. to −55° C.

9. The method of claim 1, further comprising maintaining the processing gas present within the processing chamber at a pressure of between 2 and 60 mTorr.

10. The method of claim 9, wherein maintaining the processing gas present within the processing chamber comprises further maintaining the processing gas between 10 and 20 mTorr.

11. The method of claim 1, wherein the processing gas includes at least one additive gas, the additive gas containing a halogen-based gas or a sulfuric-based gas.

12. The method of claim 1, wherein the processing gas includes at least one additive gas selected from the group consisting of CF₄, CHF₃, CH₂F₂, CH₃F, N₂, CH₄, HBr, SOCl₂, COS, SO₂, and SF₆.

13. The method of claim 12, wherein a ratio of the at least one additive gas to total gases is 0.01.

14. The method of claim 1, wherein exposing the portion of the Ru layer to the processing gas further comprises forming a portion of an interconnect structure in the Ru layer.

15. A method of etching ruthenium (Ru), the method comprising:
exposing a portion of a substrate containing an exposed Ru layer to a processing gas comprising a halogen containing gas and an oxygen containing gas, the halogen containing gas is Cl₂, the oxygen containing gas is O₂, wherein a ratio of Cl₂ to O₂ is between 1:20 to 1:1 standard cubic centimeters per minute (sccm), wherein the substrate is disposed on a substrate support in a processing chamber; and
maintaining a temperature of the substrate support between −70° C. to −20° C. while exposing the portion of the Ru layer to the halogen containing gas.

16. The method of claim 15, wherein the ratio of Cl₂ to O₂ further is 1:10 to 1:3 sccm.

17. The method of claim 15, further comprising forming an interconnect in the Ru layer, wherein an oxidation by-product of the exposing a portion of the Ru layer serves as passivation to cover at least one sidewall of the interconnect.

18. The method of claim 17, wherein the interconnect is tapered.

19. A processing chamber comprising:
a chamber body having a processing volume;
a substrate support disposed in the processing volume;
a controller; and
a memory for storing instructions, which, when executed by the controller, causes a method for forming a feature on a substrate disposed on the substrate support to be performed, the method comprising:
exposing a portion of a substrate containing an exposed Ru layer to a processing gas comprising a halogen containing gas and an oxygen containing gas, wherein the substrate is disposed on a substrate support in a processing chamber; and
maintaining a temperature of the substrate support between −90° C. and 20° C. while exposing the portion of the Ru layer to the halogen containing gas.

20. The processing chamber of claim 19, the processing chamber further comprising a gas panel configured to allow the processing gas to be provided into the processing volume, wherein the gas panel includes Cl₂ and O₂, and at least one or move additional gases selected from the group consisting of CF₄, CHF₃, CH₂F₂, CH₃F, N₂, CH₄, HBr, SOCl₂, COS, SO₂, and SF₆.
